(19) United States
(12) Patent Application Publication
(10) Pub. No.: US 2005/0127987 A1
(43) Pub. Date: Jun. 16, 2005

(54) Reference voltage generating circuit

(76) Inventors: Yukio Sato, Yokohama-shi (JP); Masaru Hashimoto, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/998,674

(22) Filed: Nov. 30, 2004

(30) Foreign Application Priority Data
Dec. 16, 2003 (JP) 2003-417646

(51) Int. Cl. H03K 5/153

(52) U.S. Cl. 327/539

(57) ABSTRACT

A collector and a base of a first, a second transistors are each short circuited. The second transistor has a current density larger than that of the first transistor. A first resistor is connected between the emitter of the first transistor and a ground potential node. One end of a second resistor is connected to the first transistor. One end of a third resistor is connected to the second transistor. The other end of the third resistor is connected commonly to the other end of the second resistor. An operational amplifier circuit has an inverting input terminal connected to the one end of the second resistor and a non-inverting input terminal connected to the one end of the third resistor. A reference voltage regulating output circuit is inserted between the output terminal of the operational amplifier circuit and the other ends of the second, the third resistors.

### CROSS-REFERENCE TO RELATED APPLICATIONS

This application is based upon and claims the benefit of priority from prior Japanese Patent Application No. 2003-417646, filed Dec. 16, 2003, the entire contents of which are incorporated herein by reference.

### BACKGROUND OF THE INVENTION

1. Field of the Invention

The present invention relates to a reference voltage generating circuit formed in a semiconductor integrated circuit. More particularly, the present invention relates to a reference voltage generating circuit formed by using bipolar transistors and resistors.

2. Description of the Related Art

As a constant-voltage circuit of high accuracy formed in a semiconductor integrated circuit, disclosed in Japanese Patent Application KOKAI Publication No. 11-338560 is, for example, conventionally known. In this constant-voltage circuit, a reference voltage generated from a reference voltage generating circuit is amplified by an amplifier circuit. The gain of the amplifier circuit is controlled by a trimming circuit. Thus, the value of the output voltage of the constant-voltage circuit is regulated.

In the constant-voltage circuit, even if the value of the reference voltage becomes uneven due to the irregularity in the manufacture of the semiconductor integrated circuit, the output voltage can be regulated to a desired value at a certain specific temperature by using a trimming circuit. However, when the value of the reference voltage becomes uneven, a temperature coefficient of the reference voltage also becomes uneven. Even though the output voltage is regulated to the desired value at the certain specific temperature by the trimming circuit, when the temperature is changed, the output voltage is largely altered. Therefore, when the constant-voltage circuit is applied to a device required to have low temperature coefficient characteristics, the specification of the device is difficult to be satisfied.

### BRIEF SUMMARY OF THE INVENTION

According to an aspect of the present invention, there is provided a reference voltage generating circuit includes a first transistor having a collector, an emitter and a base and in which the collector and the base are short-circuited; a second transistor having a collector, an emitter and a base in which the collector and the base are short-circuited, the emitter is connected to a first potential node and which has a current density larger than that of the first transistor, a first resistor connected in series with the first transistor, a second resistor having one end and the other end and in which the one end is connected to the collector of the first transistor, a third resistor having one end and the other end and in which the one end is connected to the collector of the second transistor and the other end is connected commonly to the other end of the second resistor, an amplifier circuit having an inverting input terminal, a non-inverting input terminal and an output terminal and in which the inverting input terminal is connected to one end of the second resistor and the non-inverting input terminal is connected to the one end of the third resistor, and a reference voltage regulating output circuit connected between the output terminal of the amplifier circuit and a common connecting node of the other ends of the second, third resistors, to generate a plurality of voltages from the voltage between the output terminal of the amplifier circuit and the common connecting node of the other ends of the second, third resistors, and to select one voltage from the plurality of voltages and outputs one voltage as a reference voltage.

### BRIEF DESCRIPTION OF THE SEVERAL VIEWS OF THE DRAWING

FIG. 1 is a circuit diagram showing the configuration of a first embodiment of a reference voltage generating circuit according to the present invention;

FIG. 2 is a circuit diagram showing a first concrete example of the reference voltage generating circuit of FIG. 1;

FIG. 3 is a circuit diagram showing the configuration of a modified embodiment of the reference voltage generating circuit of FIG. 2;

FIG. 4 is a circuit diagram showing a second concrete example of the reference voltage generating circuit of FIG. 1;

FIG. 5 is a circuit diagram showing a third concrete example of the reference voltage generating circuit of FIG. 1;

FIG. 6 is a characteristic diagram showing the simulated result of the temperature characteristics of a reference voltage when the reference voltage generating circuit of the first embodiment is operated under certain conditions;

FIG. 7 is a characteristic diagram showing the simulated result of the temperature characteristics of the reference voltage when the reference voltage generating circuit of the first embodiment is operated under different conditions from FIG. 6;

FIG. 8 is a characteristic diagram showing the simulated result of the temperature characteristics of the reference voltage when the reference voltage generating circuit of the first embodiment is operated under different conditions from FIG. 6 and FIG. 7;

FIG. 9 is a characteristic diagram showing the simulated result of the temperature characteristics of the reference voltage when the reference voltage generating circuit of the first embodiment is operated under different conditions from FIG. 6 through FIG. 8;

FIG. 10 is a characteristic diagram showing the simulated result of the temperature characteristics of the reference voltage when the reference voltage generating circuit of the first embodiment is operated under different conditions from FIG. 6 through FIG. 9;

FIG. 11 is a circuit diagram showing a fourth concrete example of the reference voltage generating circuit of FIG. 1; and

FIG. 12 is a circuit diagram showing the configuration of a second embodiment of a reference voltage generating circuit according to the present invention.

### DETAILED DESCRIPTION OF THE INVENTION

<First Embodiment>

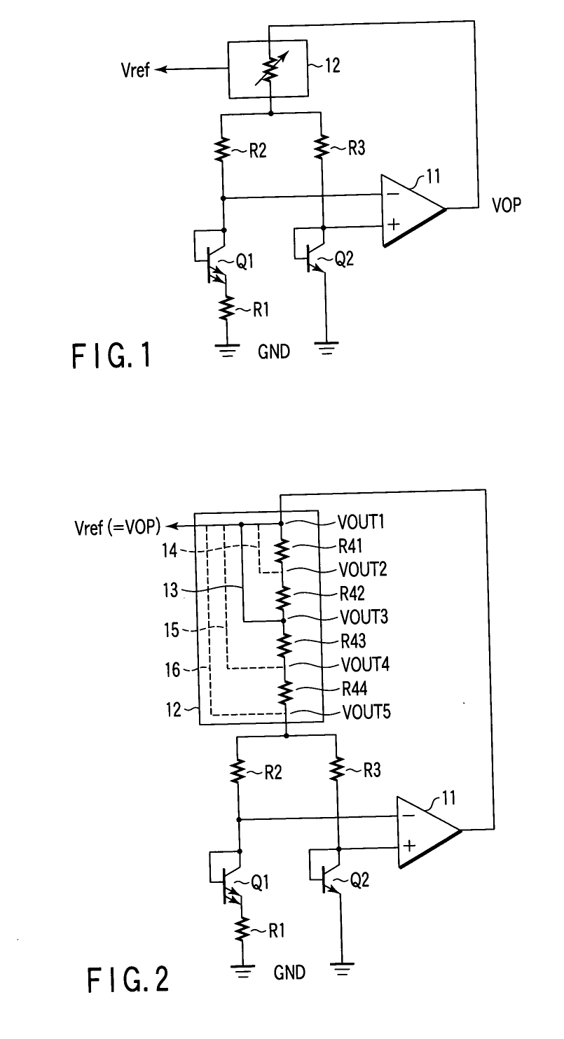

FIG. 1 shows the schematic configuration of the reference voltage generating circuit of the first embodiment. First and second npn type bipolar transistors Q1, Q2 are operated in different emitter current densities from each other. In this embodiment, the emitter current density of the first transistor Q1 is smaller than that of the second transistor Q2.

In this embodiment, as the first transistor Q1 with low emitter current density, a multiemitter type transistor is used. In the multiemitter type transistor, a collector and a base are short-circuited and diode-connected. As the second transistor Q2, a transistor with a collector and a base short-circuited and diode-connected. A first resistor R1 is connected between the emitter of the first transistor Q1 and the node of a ground potential GND. One end of a second resistor R2 is connected to the collector of the first transistor Q1. The emitter of the second transistor Q2 is connected to the node of the ground potential GND. One end of the third resistor R3 is connected to the collector of the second transistor Q2. The other end of the third resistor R3 and the other end of the second resistor R2 are commonly connected.

An operational amplifier circuit 11 has an inverting input terminal (−), a non-inverting input terminal (+) and an output terminal. The non-inverting input terminal (−) of the operational amplifier circuit 11 is connected to the one end of the second resistor R2. The non-inverting input terminal (+) of the operational amplifier circuit 11 is connected to the one end of the third resistor R3. A reference voltage regulating output circuit 12 is inserted between the output terminal of the operational amplifier circuit 11 and the other end common connecting node at the other ends of the second resistor R2 and the third resistor R3.

The reference voltage regulating output circuit 12 has a plurality of resistors. A plurality of voltages are generated from the voltage between the output terminal of the operational amplifier circuit 11 and the other end common connecting node of the other ends of the second and third resistors R2, R3. The reference voltage regulating output circuit 12 has functions of selecting one voltage from the plurality of the voltages and outputting a reference voltage Vref. This will be described in detailed later.

Incidentally, it is sufficient that the first resistor R1 is connected in series with the first transistor Q1, or the first resistor R1 is connected between the collector of the first transistor Q1 and the inverting input terminal (−) of the operational amplifier circuit 11.

The resistance values of the second resistor R2 and the third resistor R3 are set relatively large. The resistance values of the second and third resistors R2, R3 are set as follows. When the circuit is operated, voltage drops VR2, VR3 generated when currents flow to both the resistors R2 and R3 become larger than the voltages VBEQ1, VBEQ2 generated between the bases and the emitters of the first and second transistors Q1 and Q2.

For the convenience of the description, it should be noted that the emitter area of the first transistor Q1 is eight times as large as that of the second transistor Q2, and the resistance values of the second resistor R2 and the third resistor R3 are equal to each other (R2=R3).

The circuit becomes an operating state. A voltage VOP is output from the operational amplifier circuit 11. Then, current flows through the reference voltage regulating output circuit 12, the second resistor R2, the first transistor Q1 and the first resistor R1 in series. Thus, the voltage VBEQ1 is generated between the base and the emitter of the first transistor Q1. The voltage drop occurs at both ends of the first resistor R1. The first resistor R1 is connected in series between the emitter of the first transistor Q1 and the ground potential GND. Therefore, the collector voltage of the first transistor Q1 becomes a voltage shifted to a high potential side. In this case, the shifted voltage is obtained by shifting the voltage VBEQ1 between the base and the emitter by the voltage drop part occurred at both ends of the first resistor R1. A current flows to the second transistor Q2. Thus, the voltage VBEQ2 is generated between the base and the emitter of the second transistor Q2. The operational amplifier circuit 11 amplifies a voltage of the difference between an added voltage and the voltage VBEQ2 between the base and the emitter of the second transistor Q2. In this case, the added voltage is obtained by adding the voltage VBEQ1 between the base and the emitter of the first transistor Q1 to the voltage generated at the both ends of the first resistor R1. The output VOP of the operational amplifier circuit 11 is supplied to the other end common connecting node of the second resistor R2 and the third resistor R3 through the reference voltage regulating output circuit 12.

It is now assumed that the output voltage VOP of the operational amplifier circuit 11 is lower than the predetermined value. Then, the currents flowing to the reference voltage regulating output circuit 12 and the first to the third resistors R1 to R3 are reduced from the predetermined value. The resistance values of the second resistor R2 and the third resistor R3 are relatively largely set. Additionally, when the circuit is operated, the resistance values of the second and third resistors R2, R3 are set in the following manner. The voltage drops VR2, VR3 generated when the currents flow to both the resistors R2 and R3 become larger than the voltages VBEQ1, VBEQ2 generated between the bases and the emitters of the first and second transistors Q1, Q2. Therefore, the voltages VBEQ1, VBEQ2 become substantially the same as those in the case of the above-mentioned predetermined value. Suppose that the current flowing to the first resistor R1 is “I1”. Then, the input potential of the operational amplifier circuit 11 at the inverting input terminal (−) side becomes VBEQ1+R1·−I1. Then, the input potential at the non-inverting input terminal (+) side becomes VBEQ2. The output voltage VOP of the operational amplifier circuit 11 is lower than that in the case of the predetermined value. Therefore, the input potential at the non-inverting input terminal (+) becomes lower than the input potential at the inverting input terminal (−), and the output voltage VOP of the operational amplifier circuit 11 is raised to a certain high value.

On the contrary, when the output voltage VOP of the operational amplifier circuit 11 is higher than the predetermined value, the voltage generated at the first resistor R1 becomes high. By the same reason as that in the above-mentioned description, the input potential of the operational amplifier circuit 11 at the inverting input terminal (−) side becomes higher than the input potential of the non-inverting input terminal (+) side, and the output voltage VOP of the operational amplifier circuit 11 is lowered to a certain low value.

When the operation of the circuit becomes a stable state. The input voltage of the non-inverting input terminal (+) side of the operational amplifier circuit 11 becomes equal to that of the inverting input terminal (−) side of the operational amplifier circuit 11. At this time, currents of the same values flow to the first transistor Q1 and the second transistor Q2. As described above, the emitter area of the first transistor Q1 is formed eight times as large as that of the second transistor Q2. Therefore, a differential voltage ΔVBE of the voltages VBEQ1, VBEQ2 between the bases and the emitters of the first transistor Q1 and the second transistor Q2 is given by the following equation: In this case, the voltages VEBQ1, VBEQ2 are respectively generated at the first transistor Q1 and the second transistor Q2.

$$\begin{matrix}Δ VBE = VBEQ2 - VBEQ1 \\ = ( KT / q ) \times ln 8\end{matrix} \qquad ( 1 )$$

Here, K is a Boltzmann's constant, T is an absolute temperature, and q is an electron charge quantity.

The current of ΔVBE/R1 flows to the first resistor R1, and the current of the same value also flows to the second resistor R2. The currents of the same values respectively flow to the first transistor Q1 and the second transistor Q2. The currents of the same value flow to the second resistor R2 and the third resistor R3. And, the sum of the respective currents flows to the reference voltage regulating output circuit 12. Therefore, the output voltage VOP of the operational amplifier circuit 11 is given by the following equation (2), wherein R4 is the resistance value between the both ends of the reference voltage regulating output circuit 12.
VOP=VBEQ2+(ΔVBE/R1)×(R2+2×R4) (2)

Here, the ΔVBE is proportional to the absolute temperature T as shown in the above-mentioned equation (1). Therefore, the ΔVBE becomes large when the temperature rises. On the other hand, the value of the VBEQ2 is lowered when the temperature rises. Therefore, the temperature characteristics of the output voltage VOP can be eliminated by suitably selecting the respective resistance values R1 to R4.

Further, the temperature characteristics are stabilized and an accurate reference voltage Vref can be outputted by regulating the resistance value R4 of the reference voltage regulating output circuit 12.

<First Concrete Example of First Embodiment>

FIG. 2 is a circuit diagram showing a first concrete example of the reference voltage generating circuit of FIG. 1. A resistor circuit is provided in the reference voltage regulating output circuit 12. The resistor circuit includes a plurality of resistors that are connected in series with each other. The resistors are, for example, four resistors R41, R42, R43 and R44 in the first example. Further, any one node is selected from the other end of the reference voltage regulating output circuit 12 and from series connecting nodes of the four resistors R41, R42, R43 and R44. Selected node and the one end of the reference voltage regulating output circuit 12 are connected by a wiring. In the example of FIG. 2, a series connecting node of the resistors R42 and R43 and one end of the reference voltage regulating output circuit 12 are connected by a wiring 13. The wiring 13 is formed at a manufacturing process. In stead of the above-mentioned wiring 13, a wiring 14 indicated by a broken line is used to connect the series connecting node of the resistors R41 and R42 and the one end of the reference voltage regulating output circuit 12. Alternatively, a series connecting node of the resistors R43 and R44 and the one end of the reference voltage regulating output circuit 12 can be connected by using a wiring 15. Further, the other end of the reference voltage regulating output circuit 12 and the one end of the reference voltage regulating output circuit 12 can be connected by using a wiring 16 indicated by a broken line. Or, it should be noted that any of the above-mentioned wirings may not be provided.

In the reference voltage regulating output circuit 12, voltages VOUT1 to VOUT5 of different values of five ways are generated from a voltage between an output terminal of an operational amplifier circuit 11 and the other end common connecting node at the other respective ends of the second and third resistors R2, R3. The wirings 13 to 16 are selectively provided. Therefore, one voltage is selected from the voltages of five ways. Then, a reference voltage Vref is outputted. In other words, the resistance value between the both ends of the reference voltage regulating output circuit 12 can be regulated by selectively providing the above-mentioned wirings 13 to 16 or not providing the wirings. And, the reference voltage Vref of a desired value is outputted from one end of the reference voltage regulating output circuit 12 by regulating this resistance value.

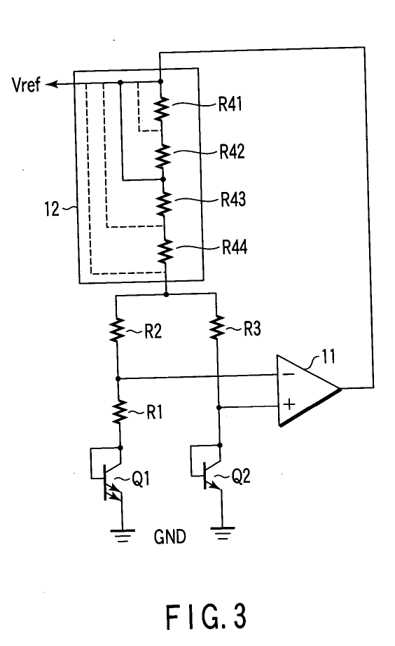

Incidentally, in the reference voltage generating circuit of FIG. 2, an example that the first resistor R1 in FIG. 1 is altered to be connected in series with the emitter side of a first transistor Q1 is shown. However, as described above, as shown in FIG. 3, the first resistor R1 may be connected between the collector of the first transistor Q1 and an inverting input terminal (−) of the operational amplifier circuit 11.

<Second Concrete Example of First Embodiment>

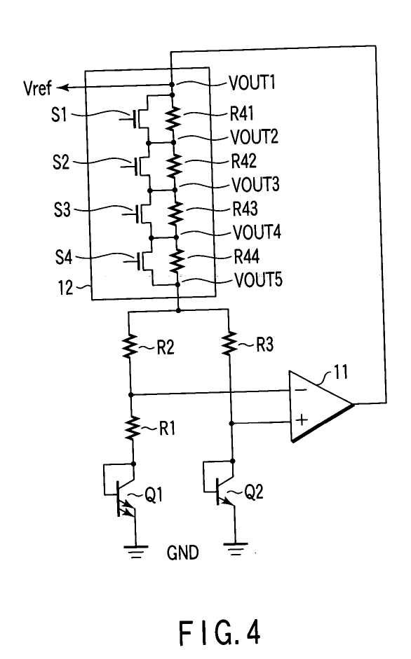

FIG. 4 shows a second concrete example of the reference voltage regulating output circuit of FIG. 1. A resistor circuit is provided in the reference voltage regulating output circuit 12. The resistor circuit includes a plurality of resistors that are connected in series with each other. The resistors are, for example, four resistors R41, R42, R43 and R44 in the second example. Further, four switch elements S1 to S4 are connected in parallel with the four resistors R41, R42, R43 and R44. The four switch elements S1 to S4 are controlled to be conducted in response to respective control signals.

In the reference voltage regulating output circuit 12, voltages VOUT1 to VOUT5 of different values of five ways are generated between the output terminal of the operational amplifier circuit 11 and the other end common connecting node at the other ends of the second, third resistors R2, R3. The switch elements S1 to S4 are controlled to be conducted in response to the control signals. Thus, one voltage is selected from the voltages of the five ways and is outputted as a reference voltage Vref. In other words, a resistance value between the both ends of the reference voltage regulating output circuit 12 can be regulated by controlling to conduct the switch elements S1 to S4. And, the reference voltage Vref of a desired value is outputted from one end of the reference voltage regulating output circuit 12 by regulating this resistance value.

Incidentally, in the reference voltage generating circuit of FIG. 4, an example that the first resistor R1 in FIG. 1 is connected between the collector of the first transistor Q1 and the inverting input terminal (−) of the operational amplifier circuit 11, is shown. However, as described above, the first resistor R1 may be connected between the emitter of the first transistor Q1 and the ground potential GND.

<Third Concrete Example of First Embodiment>

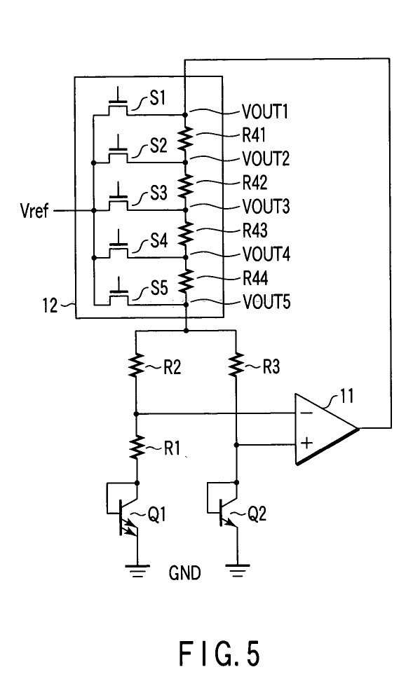

FIG. 5 shows a third concrete example of the reference voltage generating circuit of FIG. 1. A resistor circuit is provided in the reference voltage regulating output circuit 12. The resistor circuit that includes a plurality of resistors is connected in series with each other. The resistors are, for example, four resistors R41, R42, R43 and R44 in the third example. Further, five switch elements S1 to S5 are respectively connected to one end and the other end of the resistor circuit. The five switch elements S1 to S5 are also respectively connected at the one ends to the series connecting nodes of the four resistors R41, R42, R43 and R44. The five switch elements S1 to S5 are connected at the other ends commonly. The five switch elements S1 to S5 are respectively controlled to be conducted in response to controls signals.

In the reference voltage regulating output circuit 12, voltages VOUT1 to VOUT5 of different values of five ways are generated. The voltages VOUT1 to VOUT5 are generated between the output terminal of the operational amplifier circuit 11 and the other end common connecting node at the other ends of the second and third resistors R2 and R3. The switch elements S1 to S5 are controlled to be conducted in response to control signals. Thus, one voltage is selected from the voltages of five ways, and is outputted as a reference voltage Vref.

In this case, a deviation is generated in both ±directions as desired values of the resistance value of a resistor, a current gain and the like of a transistor as a center, due to the unevenness in manufacture. In the case of no deviation, the respective constants are set in the following manner. The voltage VOUT3 of the series connecting node of two resistors R42, R43 may become a desired reference voltage. The two resistors R42, R43 are disposed at the center of four resistors R41 to R44.

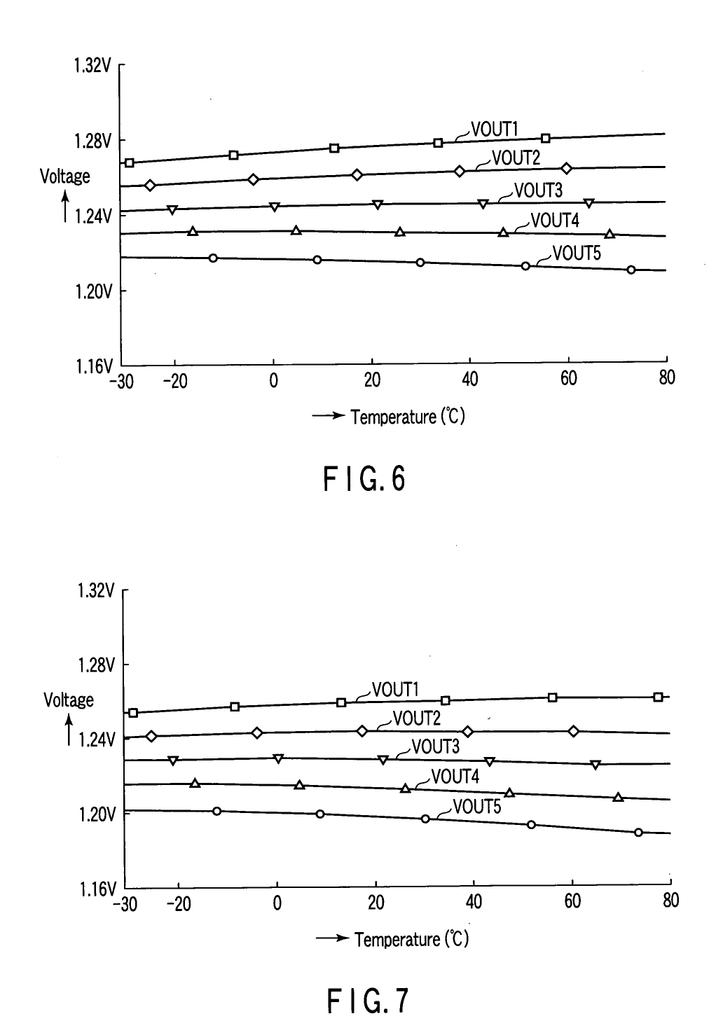

FIG. 6 shows the simulated result of the relationship between a temperature and the voltages VOUT1 to VOUT5. The simulated result is that the current gain of the transistor becomes a central value in the previous state. The previous state is that the reference voltage is regulated in the reference voltage generating circuit shown in FIG. 2 to FIG. 5.

Here, the temperature characteristics of the voltage VOUT3 is substantially flat. Its value is about 1.24V. The value of this voltage VOUT3 is slightly changed according to a manufacturing process. However, the value of this voltage VOUT3 is regarded as being an ideal value.

FIG. 7 shows the simulated result of the relationship between a temperature and the voltages VOUT1 to VOUT5. The simulated result is that the current gain of the transistor is deviated twice as large as the central value in the previous state. The previous state is that the reference voltage is regulated in the reference voltage generating circuit shown in FIG. 2 to FIG. 5.

The current gain of the transistor is deviated from the central value. However, the value of the ΔVBE is not changed. The current gain becomes twice as large as the central value. Thus, the value of the saturated current of the transistor becomes double. Therefore, the value of the VBE is reduced. The voltages VOUT1 to VOUT5 are lowered by the value of the VBE as compared with a case that the current gain as shown in FIG. 6 is a central value. In this case, the voltage VOUT2 of the series connecting node of two resistors R41, R42 becomes substantially 1.24V. And, the temperature characteristic of the voltage VOUT2 becomes the best as compared with the other temperature characteristics.

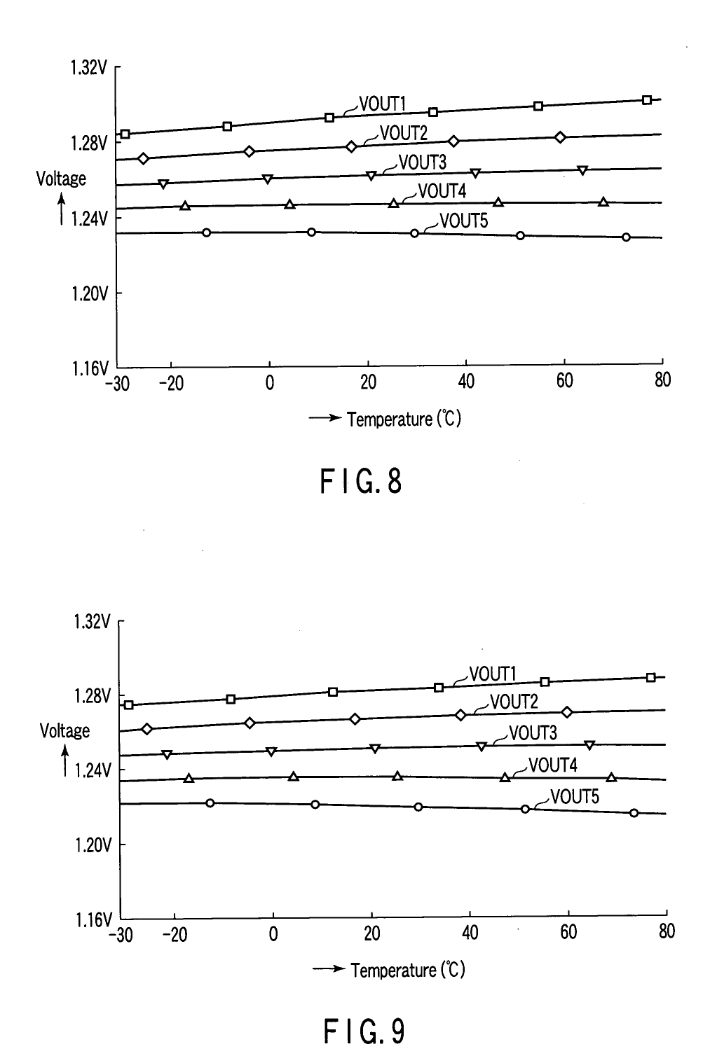

FIG. 8 shows the simulated result of the relationship between the temperature and the voltages VOUT1 to VOUT5 of a predetermined case. The predetermined case is that the current gain of the transistor is deviated to 1/2 of a central value and manufactured in the previous state. The previous case is that the reference voltage is regulated in the reference voltage generating circuit shown in FIG. 2 to FIG. 5.

The current gain of the transistor is deviated from the central value. However, the value of the ΔVBE is not changed. The current gain becomes 1/2 as large as the central value. Thus, the value of the saturated current of the transistor becomes 1/2. Therefore, the value of the VBE is increased. The voltages VOUT1 to VOUT5 are each raised by the value of the VBE as compared with a case that the current gain as shown in FIG. 6 is a central value. In this case, the voltage VOUT4 of the series connecting node of two resistors R43, R44 becomes substantially 1.24V. And, the temperature characteristic of the voltage VOUT4 becomes the best as compared with the other temperature characteristics.

FIG. 9 shows the simulated result of the relationship between a temperature and voltages VOUT1 to VOUT5 of a predetermined case. The predetermined case is that a series resistance value of the entire resistor circuit including resistors R41 to R44 is lowered by 20% with respect to a central value in the previous state. The previous state is that a reference voltage is regulated in the reference voltage generating circuit shown in FIG. 2 to FIG. 5.

The series resistance value of the entire resistor circuit becomes low. Then, a current flowing to the transistor is increased. Therefore, the values of voltages VOUT1 to VOUT5 respectively become higher as compared with a case that the current gain shown in FIG. 6 is a central value.

On the other hand, it is considered the case that the series resistor value of the entire resistor circuit is deviated by 20% higher than the central value. When the series resistance value of the entire resistor circuit becomes high, a current flowing to the transistor is reduced. Therefore, the values of the voltages VOUT1 to VOUT5 are respectively lowered as compared with a case that the current gain as shown in FIG. 6 is a central value.

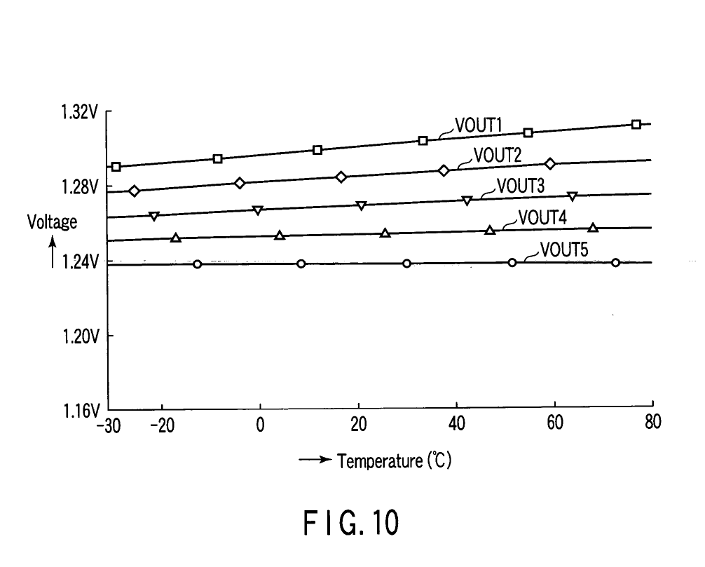

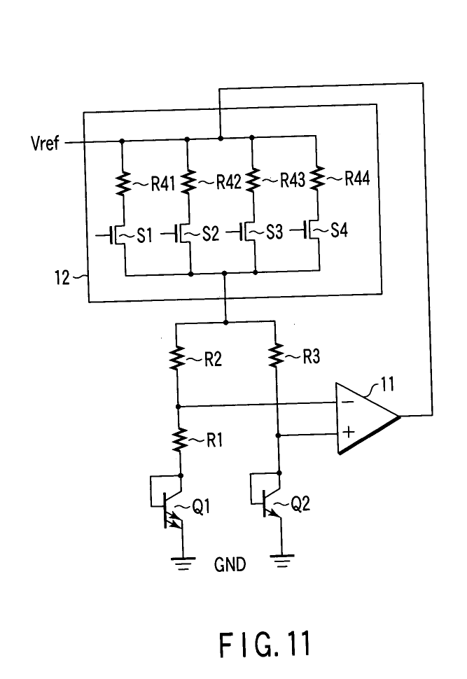

FIG. 10 shows the simulated result of the relationship between a temperature and the voltages VOUT1 to VOUT5 of a predetermined case. The predetermined case is that the series resistance value of the entire resistor circuit including resistors R41 to R44 is lowered by 20% as compared with a central value and the current gain of the transistor is deviated by 1/2 of the central value in the previous state. The previous state is that the reference voltage is regulated in the reference voltage generating circuit shown in FIG. 2 to FIG. 5.

The current gain of the transistor becomes 1/2 of a central value. Then, the value of the saturated current of the transistor becomes 1/2. Therefore, the value of VBE becomes large. Further, the series resistance value of the entire resistor circuit is lowered. Then, the current flowing to the transistor is increased. Thus, the values of voltages VOUT1 to VOUT5 respectively become high as compared with a case that the current gain as shown in FIG. 6 is a central value.

On the other hand, the series resistor value of the entire resistor circuit is deviated by 20% higher than the central value. And, the current gain of the transistor is deviated twice as large as a central value is considered. The current gain becomes twice as large as the central value. Then, the value of the saturated current of the transistor becomes double.

Then, the value of the VBD is reduced. Further, the series resistance value of the entire resistor circuit becomes high. Then, the current flowing to the transistor is reduced. Thus, the values of the voltages VOUT1 to VOUT5 are respectively lowered as compared with a case that the current gain as shown in FIG. 6 is the central value.

The simulated results as described above are summarized. It is understood that any of the voltages VOUT1 to VOUT5 becomes about 1.24V for the various unevenness of the series resistance value of the entire resistor circuit. And, it is also understood that the current gain of the transistor and preferable temperature characteristics are provided.

<Fourth Concrete Example of First Embodiment>

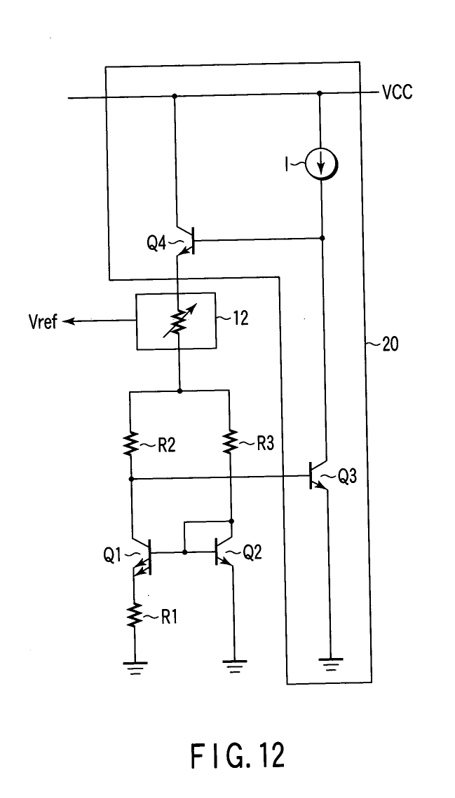

FIG. 11 shows a fourth concrete example of a reference voltage generating circuit of FIG. 1. A resistor circuit is provided in the reference voltage regulating output circuit 12. The resistor circuit includes a plurality of resistors. Or, the resistor circuit includes four resistors R41, R42, R43 and R44 in this example. The respective ends of these four resistors are connected commonly to the output terminal of the operational amplifier circuit 11. Further, a plurality of switch elements or four switch elements S1 to S4 controlled to be conducted in response to a control signal, in this example, are provided in the reference voltage regulating output circuit 12. The one ends of the four switch elements S1 to S4 are respectively connected to the other ends of the above-mentioned four resistors. And, the other terminals of the four switch elements S1 to S4 are respectively connected to the other end common connecting node of the second and third resistors R2, R3.

In the reference voltage regulating output circuit 12, the resistance value between the both ends of the reference voltage regulating output circuit 12 can be regulated by altering a combination of connecting in parallel the four resistors in the reference voltage regulating output circuit 12. Further, the resistance value can be regulated by controlling to conduct the four switch elements S1 to S4. And, a desired value of the reference voltage Vref is outputted from one end of in the reference voltage regulating output circuit 12 by regulating this resistance value.

Incidentally, in the reference voltage regulating output circuit 12, the resistance value the between both ends of the reference voltage regulating output circuit 12 may be regulated by connecting another resistor in series with the parallel connected resistors.

In the concrete example of the reference voltage generating circuit of the above-mentioned first embodiment, it is necessary to obtain a voltage having a predetermined voltage. And, it is also necessary to obtain preferable temperature characteristics as the reference voltage Vref. For this reason, when the value of the Vref is set, the series resistance value or the parallel resistance value of the resistor circuit can be finely regulated. After the value of Vref is monitored, the series resistance value or the parallel resistance value of the resistor circuit is set. Alternatively, the outputting node of the output voltage Vref is determined.

Incidentally, the amplitude of the reference voltage may be regulated by adding a buffer amplifier circuit and a trimming circuit to the rear stage of the reference voltage generating circuit of the above-mentioned first embodiment.

<Second Embodiment>

FIG. 12 shows a schematic configuration of the reference voltage generating circuit of a second embodiment. In this reference voltage generating circuit, as the first, second transistors of the same polarity operating at different emitter current densities from each other, a multiemitter type npn transistor Q1, and an npn transistor Q2 are, for example, used. In the npn transistor Q2, a collector and a base are short-circuited and diode-connected. In this embodiment, the emitter current density of the first transistor Q1 is smaller than that of the second transistor Q2.

A first resistor R1 is connected between an emitter of the first transistor Q1 and a node of a ground potential GND. One end of the second resistor R2 is connected to a collector of the first transistor Q1. An emitter of the second transistor Q2 is connected to the node of a ground potential GND. One end of the third resistor R3 is connected to the collector of the second transistor Q2. The other end of the third resistor R3 and the other end of the second resistor R2 are connected commonly to the other end of the reference voltage regulating output circuit 12.

Further, an amplifier circuit 20 for amplifying a voltage of the difference of the voltages between the bases and the emitters of the first, second transistors Q1, Q2 is connected to the collector of the first transistor Q1. A current source circuit I and two npn transistors Q3, Q4 are provided in the amplifier circuit 20. The one end of a current source circuit I is connected to the node of a power source potential Vcc, and a collector and an emitter of the transistor Q3 are connected between the other end of the current source circuit I and the node of the ground potential GND. A base of the transistor Q3 is connected to the collector of the first transistor Q1. A collector and an emitter of a transistor Q4 are connected between the nodes of the power source potential Vcc and the one end of the reference voltage regulating output circuit 12. A base of the transistor Q4 is connected to the common connecting node of the other end of the current source circuit I and the collector of the transistor Q3.

Here, as the reference voltage regulating output circuit 12, configurations as shown in FIG. 2, FIG. 3, FIG. 4, FIG. 5 and FIG. 11 may be used.

In the fundamental operation of the above-mentioned reference voltage generating circuit, a voltage ΔVBE of the difference of the voltages between the bases and the emitters of two bipolar type transistors Q1, Q2 having different emitter current densities is amplified by an amplifier circuit 20, and its amplified output is supplied to the second resistor R2. The voltage generated at the second resistor R2 is applied to the voltage VBEQ1 between the base and the emitter of the transistor Q1. The reference voltage Vref of a desired value is outputted from the reference voltage regulating output circuit 12 by regulating the resistance value between both terminals of the reference voltage regulating output circuit 12.

According to the reference voltage generating circuit of the above-mentioned second embodiment, the substantially similar operation to that of the reference voltage generating circuit of the above-mentioned first embodiment is realized, and the similar effect can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalence.

1. A reference voltage generating circuit comprising:
a first transistor having a collector, an emitter and a base and in which the collector and the base are short circuited;
a second transistor having a collector, an emitter and a base and in which the collector and the base are short circuited, the emitter is connected to a first potential node and which has a larger current density than the first transistor;
a first resistor connected in series with the first transistor;
a second resistor having one end and the other end and in which the one end is connected to the collector of the first transistor:
a third resistor having one end and the other end and in which the one end is connected to the collector of the second transistor and the other end is connected commonly to the other end of the second resistor;
an amplifier circuit having an inverting input terminal, a non-inverting input terminal and an output terminal and in which the inverting input terminal is connected to one end of the second resistor and the non-inverting input terminal is connected to one end of the third resistor; and
a reference voltage regulating output circuit connected between the output terminal of the amplifier circuit and a common connecting node of the other ends of the second, third resistors, to generate a plurality of voltages from the voltage between the output terminal of the amplifier circuit and the common connecting node of the other ends of the second, third resistors, and to select one voltage from the plurality of voltages and outputting the one voltage as a reference voltage.

2. The reference voltage generating circuit according to claim 1, wherein the first, the second transistors are npn type transistors.

3. The reference voltage generating circuit according to claim 1, wherein the first resistor is connected between the emitter of the first transistor and the first potential node.

4. The reference voltage generating circuit according to claim 1, wherein the first resistor is connected between the collector of the first transistor and the inverting input terminal of the amplifier circuit.

5. The reference voltage generating circuit according to claim 1, wherein the second, the third resistors have equal resistance values to one another.

6. The reference voltage generating circuit according to claim 5, wherein the resistance values of the second, the third resistors are set that the voltage drops generated at the second, the third resistors are larger than the voltages generated between the bases and the emitters of the first, the second transistors.

7. The reference voltage generating circuit according to claim 1, wherein the reference voltage generating output circuit includes:
a resistor circuit having one end and the other end and in which the one end is connected to the output terminal of the amplifier circuit and the other end is connected to a common connecting node of the other ends of the second, the third resistors, the resistor circuit includes a plurality of fourth resistors connected in series between the one end and the other end of the resistor circuit; and
a plurality of wirings which connects one node selected from the series connecting nodes of the plurality of fourth resistors and the other end of the resistor circuit to the one end of the resistor circuit,
the reference voltage regulating output circuit outputs the reference voltage from the one end of the resistor circuit.

8. The reference voltage generating circuit according to claim 1, wherein the reference voltage regulating output circuit includes:
a resistor circuit having one end and the other end and in which the one end is connected to the output terminal of the amplifier circuit and the other end is connected to a common connecting node of the other ends of the second, the third resistors and a plurality of fourth resistors connected in series between the one end and the other end; and
a plurality of switch elements connected in parallel with the plurality of four resistors respectively controlled to be conducted in response to a plurality of control signals,
the reference voltage regulating output circuit outputs the reference voltage from the one end of the resistor circuit.

9. The reference voltage generating circuit according to claim 1, wherein the reference voltage regulating output circuit includes:
a resistor circuit having one end and the other end and in which the one end is connected to the output terminal of the amplifier circuit and the other end is connected to a common connecting node of the other ends of the second, the third resistors, the resistor circuit includes a plurality of fourth resistors connected in series between the one end and the other end of the resistor circuit; and
a plurality of switch elements having one ends respectively connected to one end and the other end of the resistor circuit and each series connecting nodes of the plurality of fourth resistors, having the other ends respectively controlled to be conducted in response to a plurality of control signals,
the reference voltage regulating output circuit outputs the reference voltage from the other end common connecting node of the plurality of switch elements.

10. The reference voltage generating circuit according to claim 1, wherein the reference voltage regulating output circuit includes:
a resistor circuit having a plurality of fourth resistors each including one end and the other end and that the respective one ends are connected commonly to the output terminal of the amplifier circuit; and
a plurality of switch elements having one ends respectively connected to the other ends of the plurality of fourth resistors and the other ends connected to the common connecting node of the other ends of the second, the third resistors and controlled to be conducted in response to a plurality of control signals,
the reference voltage regulating output circuit outputs the reference voltage from the common connecting node of the respective one ends of the plurality of fourth resistors.

11. A reference voltage generating circuit comprising:
bipolar type first, second transistors having different current densities from one another;
an amplifier circuit connected to the first, second transistors for amplifying a voltage of the difference of the voltages between the bases and the emitters of the first, the second transistors;
a first resistor having one end and the other end and that the output of the amplifier circuit is supplied to the one end, the other end is connected to one transistor of the first, the second transistors, generating a voltage, and the generated voltage is applied between the base and the emitter of the one transistor of the first, the second transistors; and
a reference voltage regulating output circuit inserted at both ends between the output of the amplifier circuit and the first resistor and that the resistance value between both ends is regulated in response to a control signal and outputting a reference voltage of the value in response to the regulated resistance value.

12. The reference voltage generating circuit according to claim 11, wherein the first, the second transistors are npn type transistors.

13. The reference voltage generating circuit according to claim 11, wherein the reference voltage generating output circuit includes:
a resistor circuit having one end and the other end and in which the one end is connected to the output terminal of the amplifier circuit and the other end is connected to the other end of the first resistor and a plurality of second resistors connected in series between the one end and the other end; and
a plurality of wirings which connects one node selected from the series connecting nodes of the plurality of second resistors and the other end of the resistor circuit to the one end of the resistor circuit,
the reference voltage regulating output circuit outputs the reference voltage from the one end of the resistor circuit.

14. The reference voltage generating circuit according to claim 11, wherein the reference voltage regulating output circuit includes:
a resistor circuit having one end and the other end and in which the one end is connected to the output terminal of the amplifier circuit and the other end is connected to the other end of the first resistor, and a plurality of second resistors connected in series between the one end and the other end; and
a plurality of switch elements connected in parallel with the plurality of second resistors respectively controlled to be conducted in response to a plurality of control signals,
the reference voltage regulating output circuit outputs the reference voltage from the one end of the resistor circuit.

15. The reference voltage generating circuit according to claim 11, wherein the reference voltage regulating output circuit includes:
a resistor circuit having a plurality of second resistors each including one end and the other end and that the respective one ends are connected commonly to the output terminal of the amplifier circuit; and
a plurality of switch elements having one ends respectively connected to the other ends of the plurality of second resistors and the other ends connected to the other ends of the first resistor and controlled to be conducted in response to a plurality of control signals,
the reference voltage regulating output circuit outputs the reference voltage from the common connecting node of the respective one ends of the plurality of second resistors.

16. A reference voltage generating circuit comprising:
a bipolar type first transistor having a collector, an emitter and a base;
a bipolar type second transistor having a collector, an emitter and a base and in which the collector and the base are short circuited, the base is connected commonly to the base of the first transistor and which has a larger current density than the first transistor;
a first resistor connected in series with the first transistor;
a second resistor having one end and the other end and in which the one end is connected to the collector of the first transistor:
a third resistor having one end and the other end and in which the one end is connected to the collector of the second transistor and the other end is connected commonly to the other end of the second resistor;
an amplifier circuit connected to the collector of the first transistor for amplifying a voltage of the difference of the voltages between the bases and the emitters of the first and the second transistors; and
a reference voltage regulating output circuit inserted between the output node of the amplifier circuit and the other end common connecting node of the second, the third resistors, to generate a plurality of voltages from the voltage between the output terminal of the amplifier circuit and the common connecting node of the other ends of the second, third resistors, and to select one voltage from the plurality of voltages and outputting the one voltage as a reference voltage.

17. The reference voltage generating circuit according to claim 16, wherein the first resistor is connected between the emitter of the first transistor and the first potential node.

18. The reference voltage generating circuit according to claim 16, wherein the reference voltage generating output circuit includes:
a resistor circuit having one end and the other end and in which the one end is connected to the output terminal of the amplifier circuit and the other end is connected to a common connecting node of the other ends of the second, the third resistors and a plurality of fourth resistors connected in series between the one end and the other end; and
a plurality of wirings which connects one node selected from the series connecting nodes of the plurality of fourth resistors and the other end of the resistor circuit to the one end of the resistor circuit,
the reference voltage regulating output circuit outputs the reference voltage from the one end of the resistor circuit.

19. The reference voltage generating circuit according to claim 16, wherein the reference voltage regulating output circuit includes:
a resistor circuit having one end and the other end and in which the one end is connected to the output terminal of the amplifier circuit and the other end is connected to a common connecting node of the other ends of the second, the third resistors, the resistor circuit includes a plurality of fourth resistors connected in series between the one end and the other end of the resistor circuit; and
a plurality of switch elements connected in parallel with the plurality of fourth resistors and respectively controlled to be conducted in response to a plurality of control signals,
the reference voltage regulating output circuit outputs the reference voltage from the one end of the resistor circuit.

20. The reference voltage generating circuit according to claim 16, wherein the reference voltage regulating output circuit includes:
a resistor circuit having a plurality of fourth resistors each including one end and the other end and that the respective one ends are connected commonly to the output terminal of the amplifier circuit; and
a plurality of switch elements having one ends respectively connected to the other ends of the plurality of fourth resistors and the other ends connected to the common connecting node of the other ends of the second, the third resistors and controlled to be conducted in response to a plurality of control signals,
the reference voltage regulating output circuit outputs the reference voltage from the common connecting node of the respective one ends of the plurality of fourth resistors.
